(19) United States
(12) Patent Application Publication
(10) Pub. No.: US 2012/0027226 A1
(43) Pub. Date: Feb. 2, 2012

(54) SYSTEM AND METHOD FOR PROVIDING FOCUSED DIRECTIONAL SOUND IN AN AUDIO SYSTEM

(76) Inventor: Milford Desenberg, Bradenton, FL (US)

(21) Appl. No.: 12/847,668

(22) Filed: Jul. 30, 2010

(51) Int. Cl. H04R 1/02; H03G 3/20; H03G 3/02; H04N 7/18

(52) U.S. Cl. 381/105; 381/387; 348/77; 381/107; 348/E07.085

(57) ABSTRACT

A system and method for providing focused directional sound in an audio system where the system effectively uses regular speakers on servo stands with satellite speakers adapted to rotate on two axes. The system allows for the tracking of the speakers to focus the sound toward a person or persons as they move within the room, thereby providing for a real-time optimal sound in relation to the movement of the persons. Sensors for tracking and activating the servos can be done using infrared technology, facial recognition technology or radio frequency technology.

### FIELD OF THE INVENTION

The invention relates to the controlling and focusing of directional sound in an audio system.

### BACKGROUND OF THE INVENTION

Home audio systems and home theater audio systems typically use speaker systems that lack the ability to change the optimal focal point of the sound relative to the ear of the person listening to the audio. That is, they focus the sound to a single focal optimal point. As a person moves to different spots in the room, the sound effect to that person changes.

Tweeters are highly directional and as a result, the best speaker systems still only have a small “sweetspot” when they sound better than live. The current systems assume a stationary person is listening to the audio and the prior art lacks a system that allows for optimally focusing the sound to locations specific to the movement of the person listening to the sound.

Headphones direct the tweeter directly into the ear but are uncomfortable and can damage hearing.

### SUMMARY OF THE INVENTION

One method is to use radio frequency transmitters where a person would wear the transmitter. The present invention effectively uses regular speakers on servo stands and satellite tweeter or tweeters or whole speakers or full range cone or full range speaker with each individual cone moving inside speaker adapted to rotate on two axes to provide sound that is much richer and similar to that produced in headphones.

The invention allows for the tracking of the speakers to focus the sound toward a person as the person moves within the room, thereby providing for a real-time optimal sound in relation to the movement of the person.

Sensors for tracking and activating the servos can be done by one of several ways. The receivers would be in electrical communication with each of the servo electrical systems that activate the servo. Using triangulation, the servos would rotate to direct the sound toward each new position of the person. A second method would use infrared technology. An infrared camera would be located so that it is in electrical communication with the servo circuitry of each associated satellite tweeter. As the person moves in the room, the infrared sensors sense the location of the person by the generated or sensed heat of the person and the servos would then be activated to appropriately rotate the satellite speakers about two axes (up and down and right and left to move reflected sound to a different location) to direct the sound toward each new position of the person. A third method is to utilize facial recognition software that can be operated from a central computer or incorporated in the electronics of the combination servo/webcam/satellite tweeter system. For example, a electrical box associated with each satellite tweeter could include the software processing circuitry to operate the facial recognition software which will electronically activate the sensors rotating the satellite speaker as the facial recognition also recognizes the change of the position of the person in the room. Effectively as the webcam tracks the person's face or ears and rotates by means of the servo, the satellite speaker in turn rotates to direct the sound toward the person as the person moves within the room.

Each tweeter has associated tracking circuitry that allows for independent operation of each individual speaker. A central control circuitry is not needed. Of course, the tracking circuitry can also be incorporated in a computer or some other device having specialized circuitry to track all people in a room and to point the individual speaker toward individuals or groups of individuals. Although no rewiring would be required to set up the circuitry but clearly the present invention can be adapted in this manner to cover individuals or groups of people in a larger room.

Another feature of the present invention is to incorporate processing circuitry that delays in milliseconds and changes (lowers) in volume of speakers closest to a person and to turn down volume for speakers closest to the person.

Tracking circuitry could also be centralized in an amplifier driving the audio system where individual speaker volume can readily be controlled as the sensors (facial recognition, infrared or radio frequency) sense movement by people in the room.

Other embodiments can relate to a tracking mode as the speaker direction follows a person or a group of persons. For example, the servo/speaker can be configured to track a remote control device that the person carries and can have a manual adjustment for the location of the remote with respect to the person's ears. Another embodiment involves the use of preset locations where the speaker direction is programmed in a number of preset locations and then using the remote control or on the speaker itself type in a number that corresponds to the speaker locations. The original locations can also be programmed into the remote using a standard programmable remote or one that comes with the speakers.

Another embodiment of the tracking mode is where individual speakers follow either the closest person with a remote control or RF transmitter in his hand. The remote control device could incorporate a microphone adapted to pick up ambient noise and the system can be programmed to cancel the ambient noise to provide a better quality sound at an individual's location. Directional speakers can be used so the rest of the room hears little noise. Another embodiment is where the system keeps a person's personal space quiet using noise cancellation speaker technology. The user would have a microphone on him and the speakers would produce sound to counteract the noise waves in the environment.

One remote control device could include a touch screen representative of the room and/or four buttons to manually adjust the speakers to direct sound toward a sound sweetspot location within a room or the person in the room. The touch screen can show multiple people and multiple speakers as well as what locations and directions the speakers are in. With the remote the sweetspot can moved around the room.

The system can be programmed to effectively be a location awareness acoustic feedback system. In such an embodiment, there are two modes of operation when two or more people are in a room. Each individual speaker moves or directionally aligns itself with the location of a designated individual in the room or the system can be programmed to calculate an optimal midpoint location and to direct all individual speakers toward that optimal midpoint location.

The location awareness system allows for highly directional speakers that allow for the rest of the room area to be not as loud for others that do not wish to listen, thereby also allowing for a richer sound. These highly directional speakers can be adapted to include a parabolic dish that can be attached to and behind the speaker or not attached to the speaker but located behind the speaker. The speaker assembly can be enclosed in a speaker box housing or other type of design. The speaker within the dish can move which moves the sweetspot location of the directional sound or the whole dish can move.

### BRIEF DESCRIPTION OF THE DRAWINGS

In the accompanying drawings:

FIG. 1A is a conceptual representation of an audio system utilizing infra-red thermal imaging to track a person of group of persons in a room;

FIG. 1B is a conceptual representation of an audio system utilizing radio-frequency technology to track a person of group of persons in a room;

FIG. 1C is a conceptual representation of an audio system utilizing a webcam camera and facial recognition technology to track a person of group of persons in a room;

FIG. 2A is a conceptual representation of an audio system utilizing multiple satellite speakers in a room which track and direct sound toward a person in a room;

FIG. 2B is a conceptual representation of an audio system of FIG. 2A where the person has moved within the room from the position of FIG. 2A;

FIG. 3A is a conceptual representation of an audio system utilizing multiple satellite speakers in a room which track and direct sound toward a group of persons in a room;

FIG. 3B a conceptual representation of an audio system of FIG. 3A where the group of persons has moved within the room from the position of FIG. 3A;

FIG. 4A is a conceptual representation of another embodiment of the invention using a remote controller and radio-frequency technology with means for selecting speaker use incorporated within the remote control device;

FIG. 4B is a conceptual representation of another embodiment of the invention using a remote controller and radio-frequency technology where the remote controller is carried by the person and sound can be processed to provide a richer sound through a head set being worn over the ears of the person;

FIG. 5 is a conceptual representation of another embodiment of the invention where the remote controller has a touchscreen and/or directional buttons for directing the speaker sound toward a desired direction;

FIG. 6A is a conceptual representation of another embodiment of the invention where individual speakers follow a closest person using with a transmitter and/or remote controller;

FIG. 6B is a conceptual representation of an embodiment of the invention similar to that of FIG. 6A where individual speakers follow a closest person using with a transmitter and/or remote controller;

FIG. 6C is a conceptual representation of an embodiment of the invention similar to that of FIG. 6A where individual speakers are directed toward a sound sweetspot within the room or a calculated optimal location within the room with persons scattered in various locations within the room;

FIG. 7A is a conceptual representation of a speaker utilizing a parabolic dish behind the speaker that concentrates the sound direction toward a person, group of persons or sound sweetspot location within a room;

FIG. 7B is a conceptual representation of a speaker utilizing a parabolic dish as depicted in FIG. 7A with the speaker itself rotating within the parabolic dish; and

FIG. 7C a conceptual representation of a speaker utilizing a parabolic dish of FIG. 7A where the speaker and the parabolic dish rotate in unison.

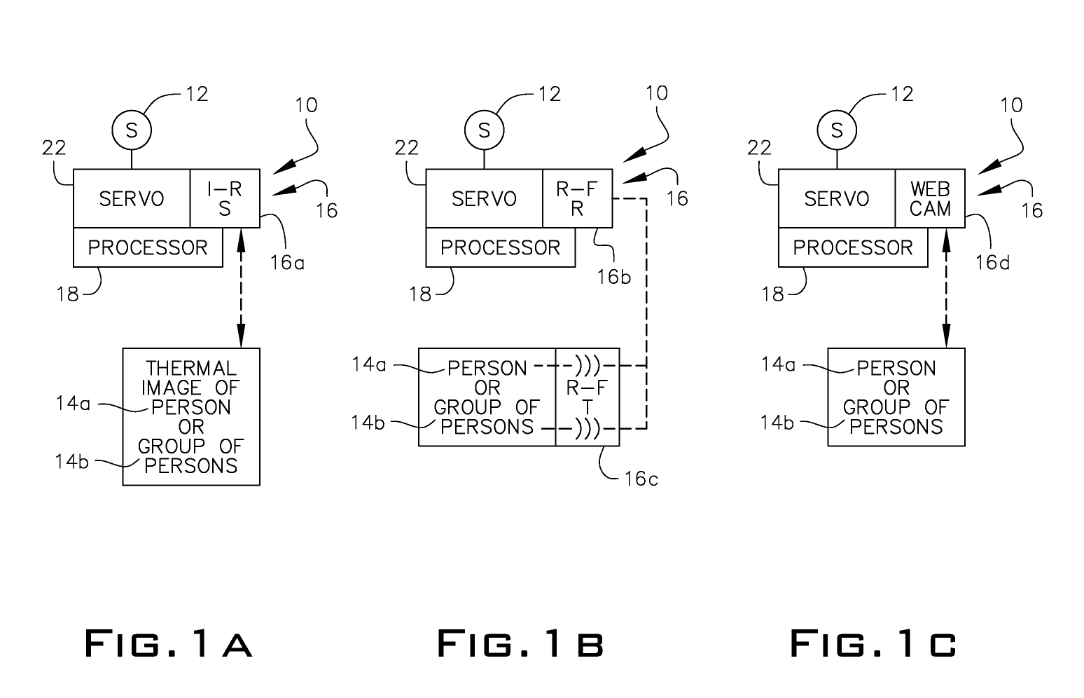

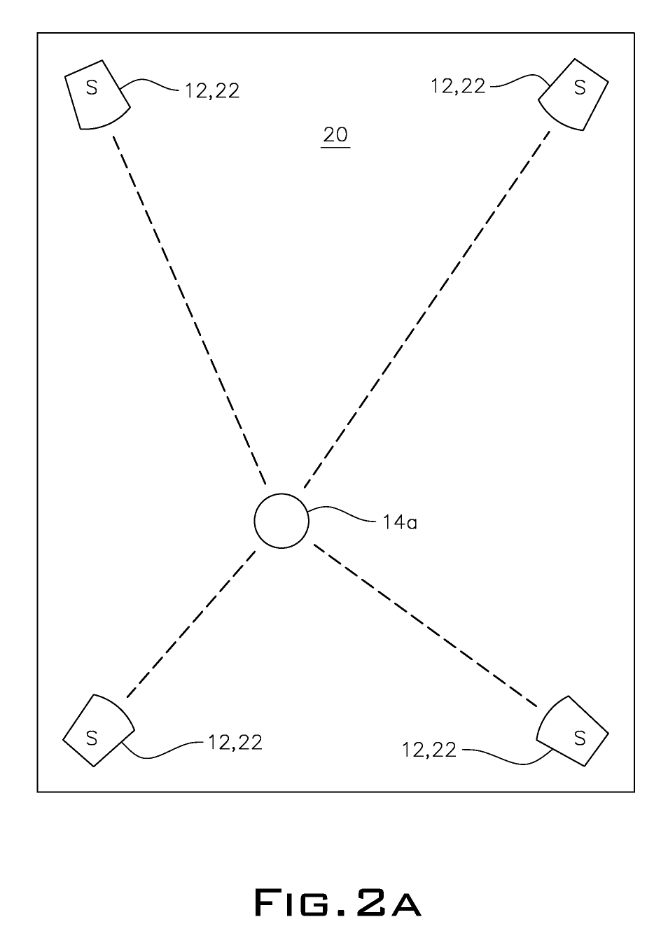

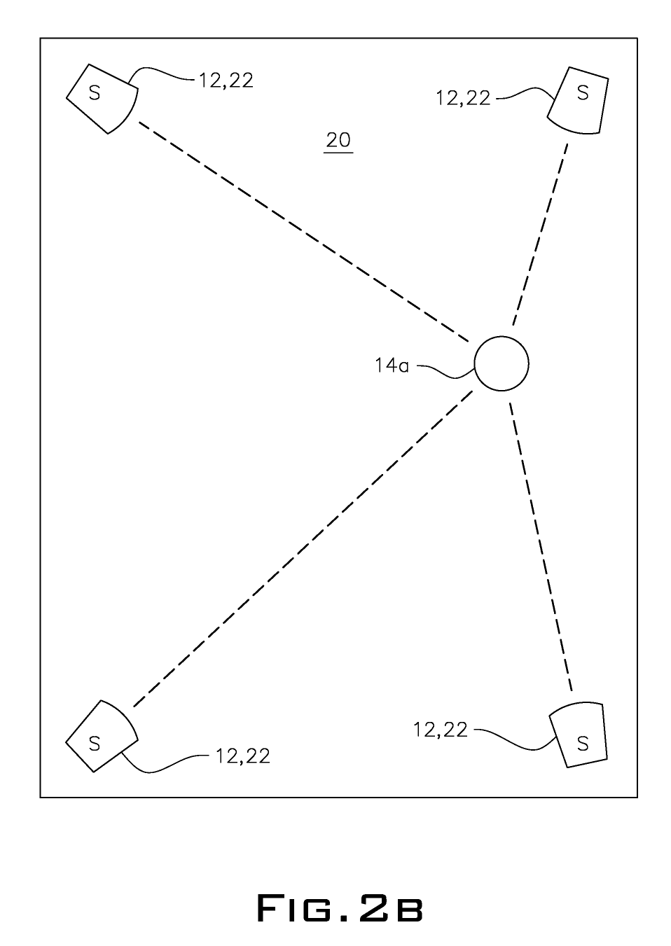

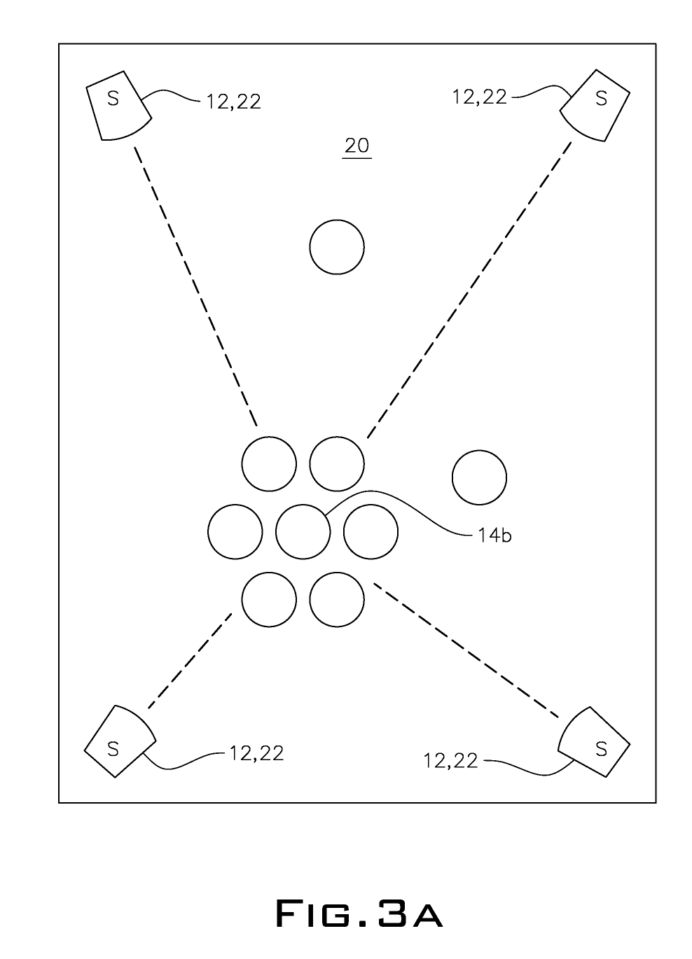

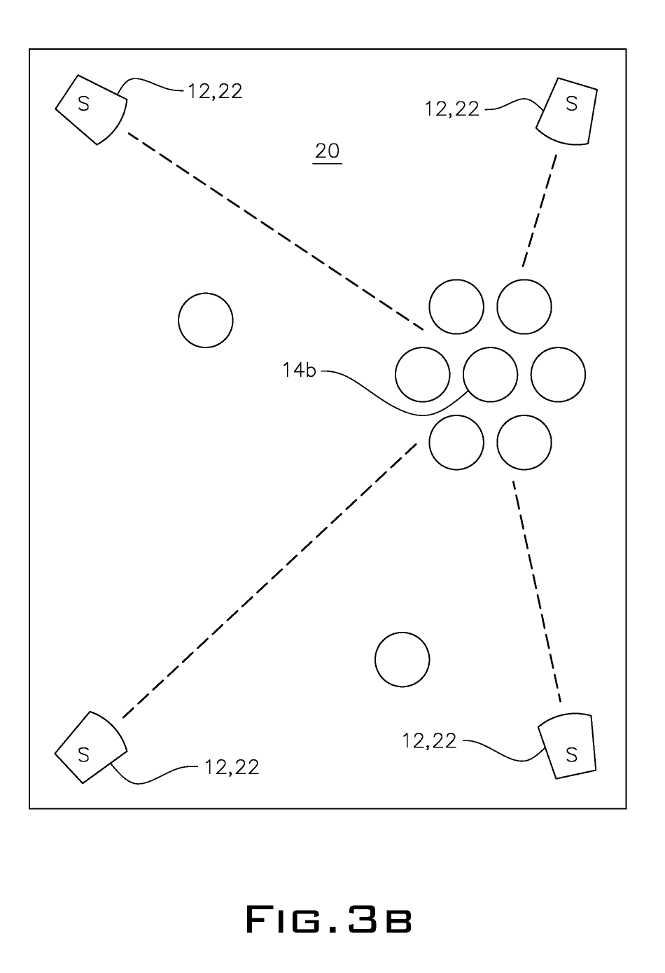

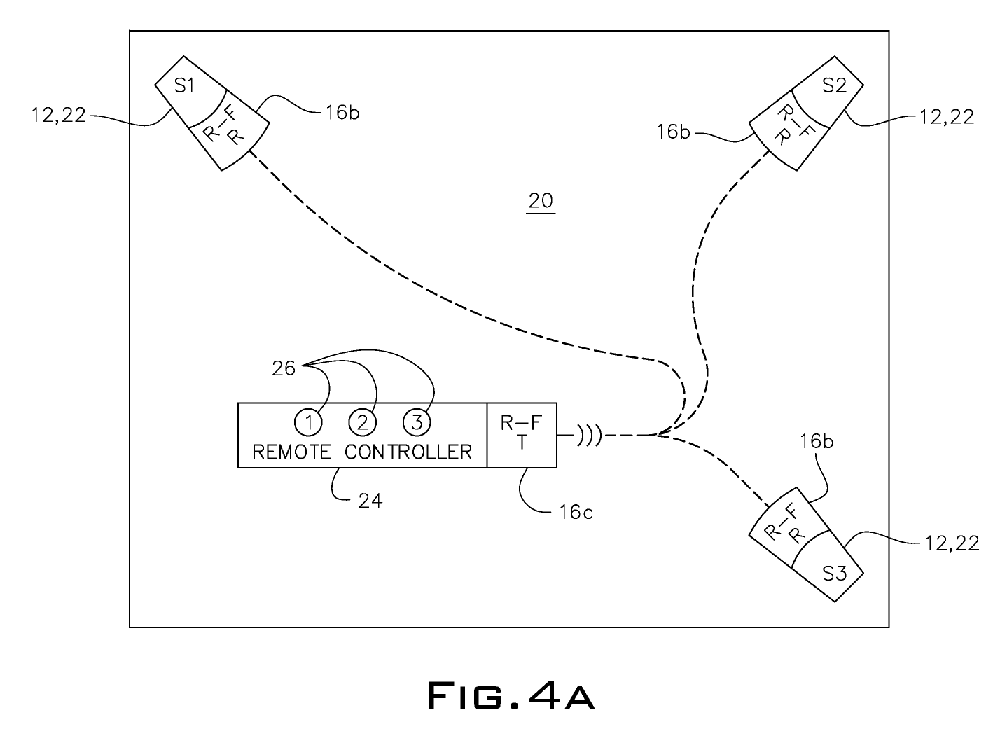

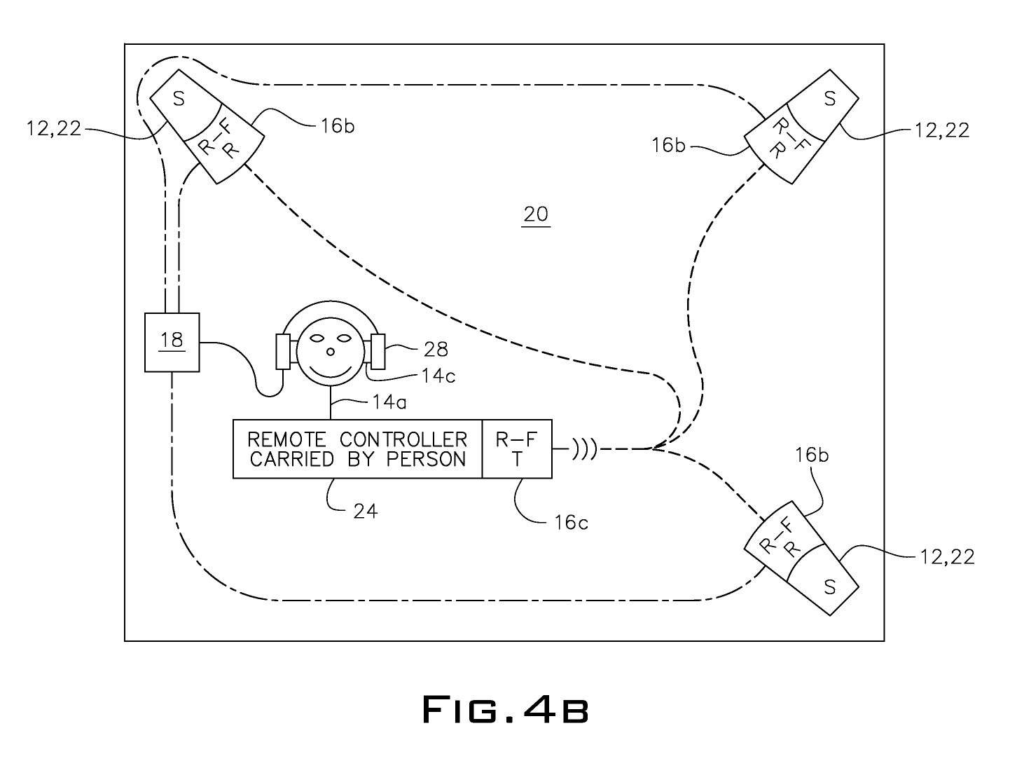

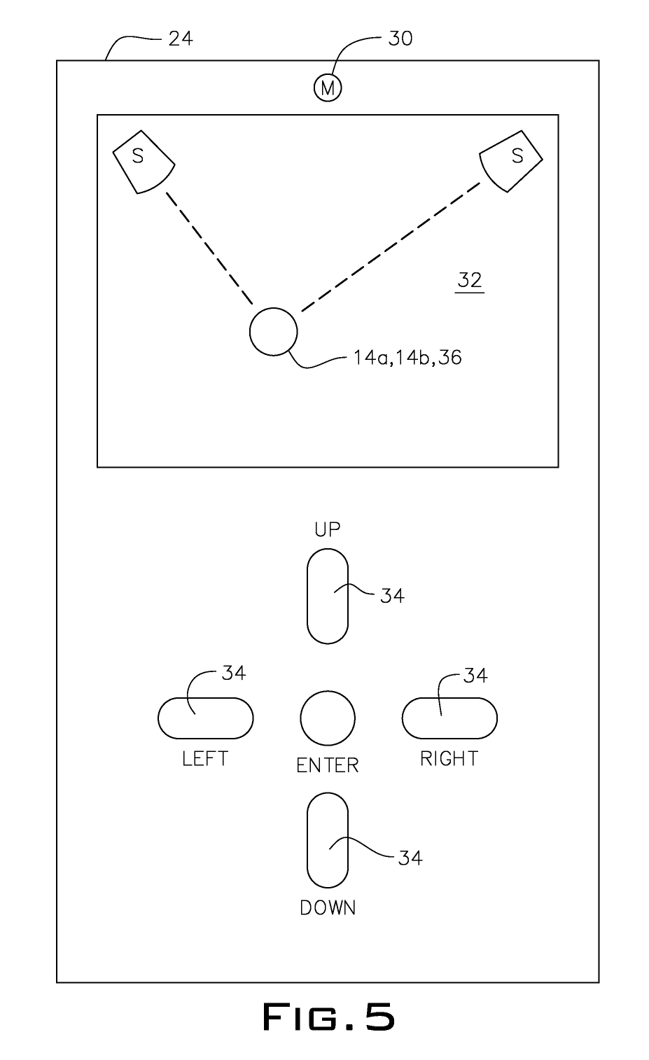

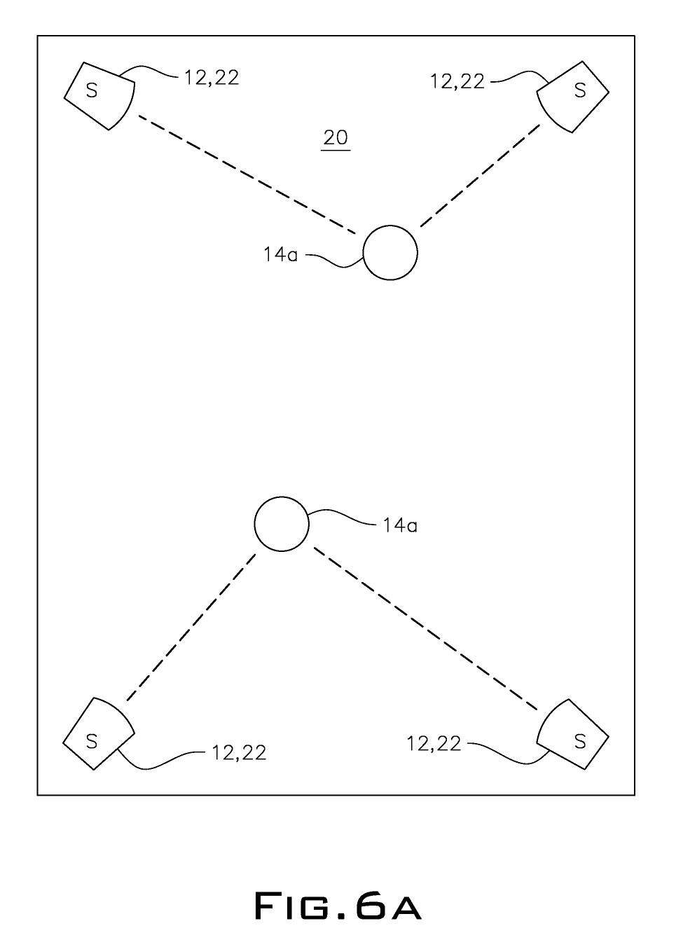

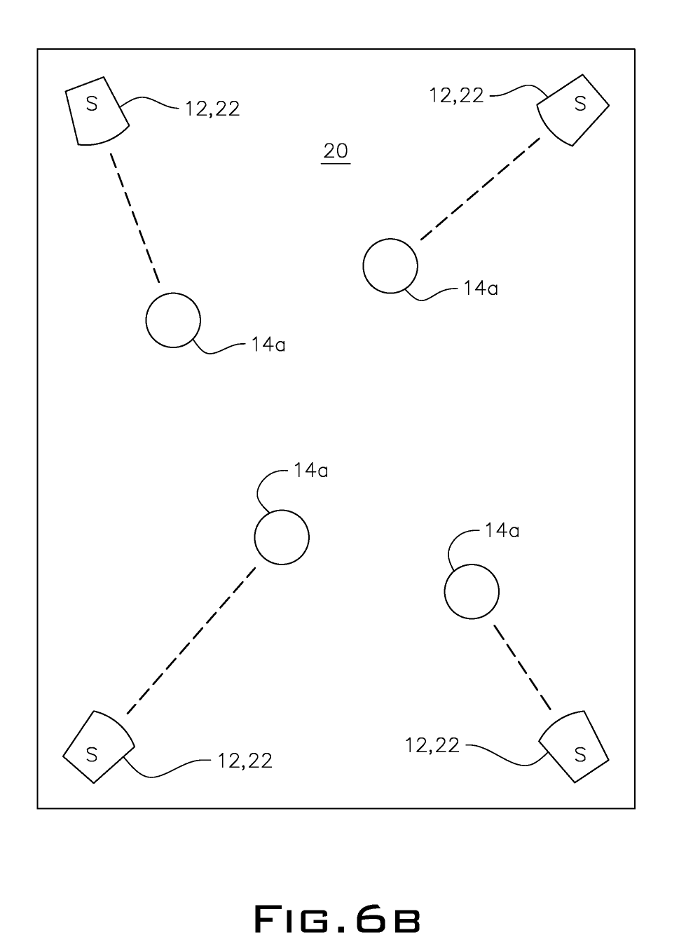

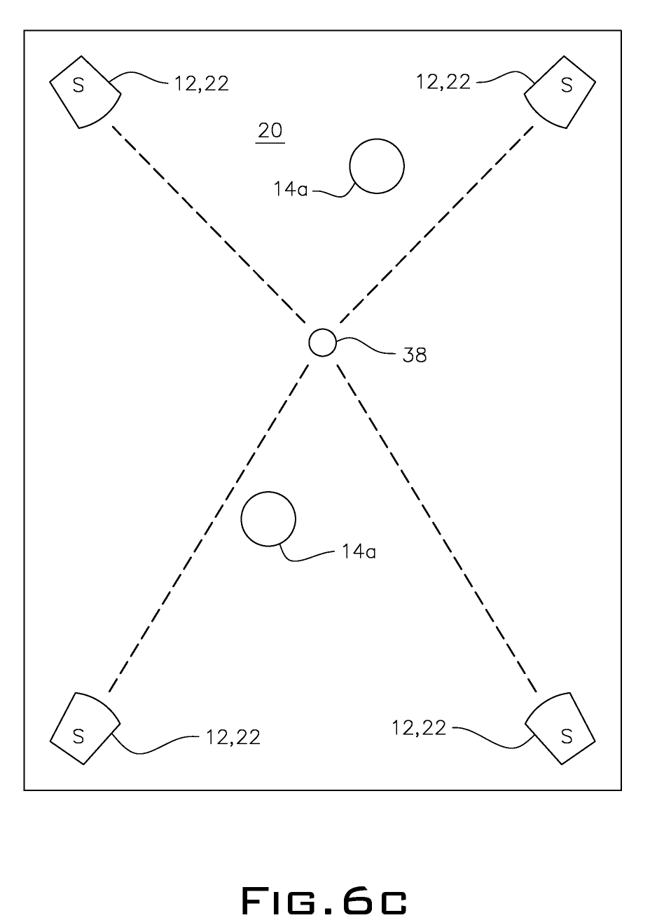

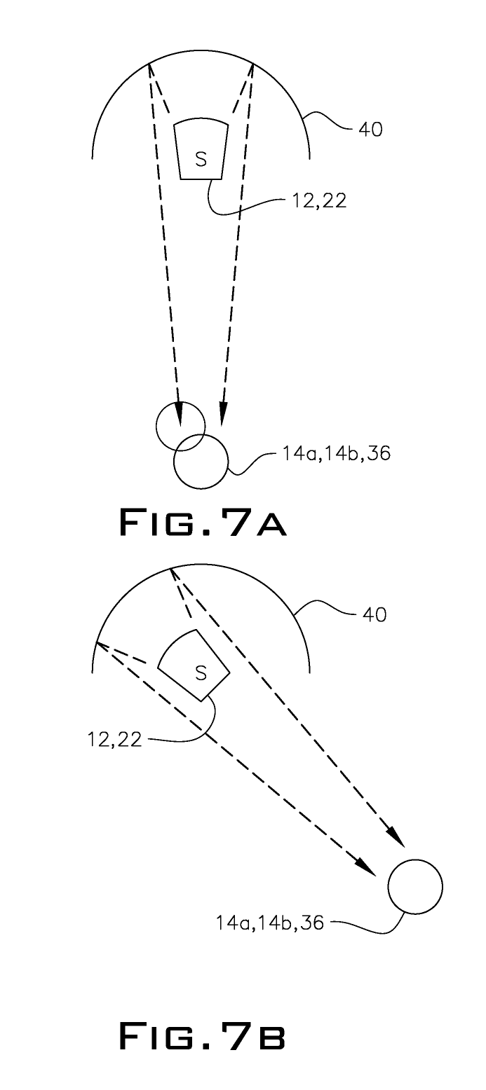

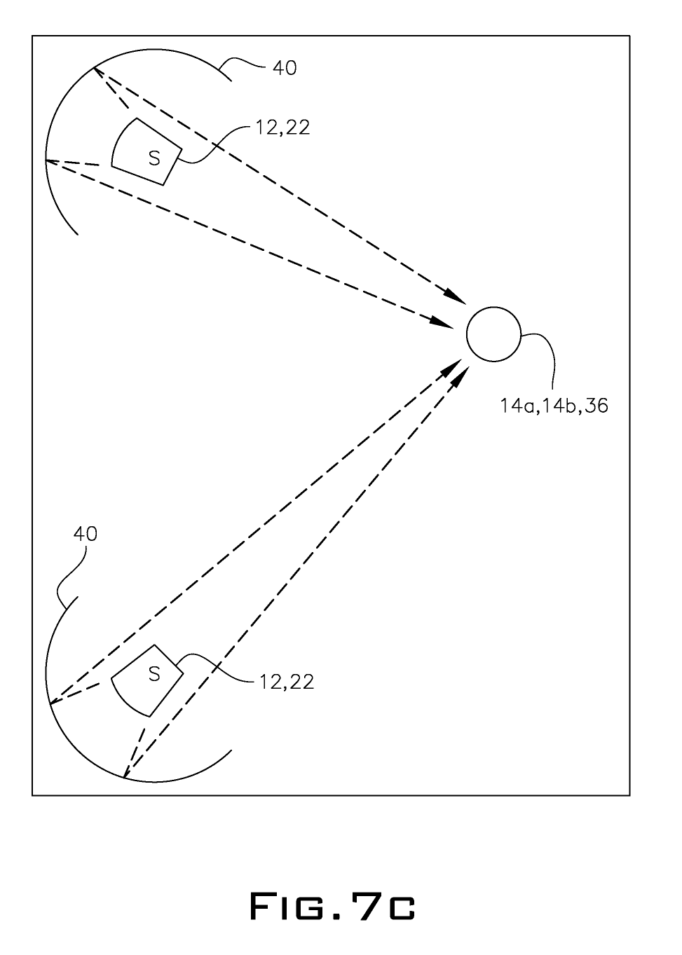

### DETAILED DESCRIPTION OF THE INVENTION

Referring now to the above described drawings, the present invention is a system and associated methodology for providing a speaker tracking system that provides focused directional sound in an audio system, and is depicted generally as 10.

The invention 10 is used with an audio speaker system having at least one speaker (or a general range frequency cone speaker as well) 12. (When used herein, the term speaker is used synonymously with tweeter speaker and general range frequency cone speaker.) The invention 10 is a system that comprises means 16 for sensing real-time movements of a person 14a or a group of persons 14b in a room 20. When sensing a group of persons 14b, typically a core or generally centralized person within the group is selected to focus on.

A servo device 22 is associated with the speaker 12 and is typically mechanically connected to the speaker 12 so as the servo device 22 is activated to rotate, the servo device 22 rotates tweeter speaker 12 to direct the audio sound resonating from the tweeter speaker 12 toward the person 14a or said group of persons 14b as the person 14a moves or the group of persons 14b move in the room 22.

Included in the invention is a processor or processing means 18 for analyzing a change of position data related to the movements and for electrically activating the servo device 22. Typically, the data flowing from the sensing means 16 is analyzed by the processor 18, which in turn communicates with the servo device 22 to rotate the speaker 12. Processing means 18 can be incorporated in a stand alone separate housing that contains a processing unit with software needed to accept the data from the sensing means 16 and transmit instructions to the servo device 22 or it can be incorporated within a single box that also includes the servo device with the sensing means 16 incorporated within the same box or the sensing means 16 kept in a separate housing. Another option is to incorporate the processing means 18 within a computer that contains the required software. It is understood that one skilled in the art of programming will be able to write the software required for analyzing the change of position data and transmitting instructions to the servo device 22.

There may be several technologies available that can be used to monitor position changes of people in a room; however, it is presumed that three of the least expensive ways of doing this are infra-red technology, radio-frequency technology and camera such as webcams.

Accordingly, one method for providing means 16 for sensing real-time movements of a person 14a or a group of persons 14b is the use of an infrared sensor 16a, which senses heat images of people. The infrared (I-R) sensor 16a communicates with the processor 18, which in turn communicates with the servo device 22. The infrared sensor 16a is typically located at or adjacent the tweeter speaker 12 and has electronic circuitry for monitoring the movements within a room 20 of the person 14a or group of persons 14b by sensing thermal imagery.

A second method of providing means 16 for sensing real-time movements of a person 14a or a group of persons 14b is by utilizing a radio frequency system comprising a radio frequency receiver 16b located at the speaker 12 and a radio frequency transmitter 16c typically worn or otherwise attached to the person 14a or someone within the group of persons 14b. Data related to the movements is transmitted to the receiver 16c, which can be located near or adjacent the speaker 12 and data received by the receiver 16c is in turn analyzed by the processor 18 for activating the servo device 22. In the accompanying drawings, as an example only, the transmitter is shown at the person location while the receiver is shown at the speaker location. It is understood that the opposite may be implemented, accordingly, when the term radio frequency first component is used hereinafter, it refers to either the transmitter component or the receiver component and when radio frequency second component is used hereinafter, it refers to the corresponding receiver component or the transmitter component. The drawings depicted show by example only the use of radio frequency technology.

A third method for providing the means 16 for sensing the movements is by utilizing a camera like a webcam 16d, which is located at the speaker 12. The camera 16d is in electronic communication with facial recognition software wherein the software is programmed to recognize the person 14a or someone within the group of persons 14b and to track the movements of the person 14a or that someone in the group of persons 14b.

Each tweeter speaker 12 can be part of a single speaker system box or they can be arranged around a room where desired as satellite speakers. Typically, when arranged as satellite speakers, there are at least two speakers as generally found in small rooms. However, it may be desired to have a plurality of speakers strategically placed within a larger room to provide for an enhanced stereo sound or a home theater experience.

When there are multiple speakers (2 or more), the invention may optionally include a functional feature that recognizes when the person moves closer to a speaker so that a volume attenuation or reduction and delay of milli-seconds so the sound waves are in sync from speakers and the volume adjusts lower closer to the listener so the decibel level is the same for both ears. In this case, the processor 18 can be programmed to adjust a volume of closer speakers as the person 14a or group of persons 14b move closer to the satellite tweeter speakers and away from others.

Another embodiment of the tracking mode is where individual speakers 12 follow either the closest person 14a with a remote control device 24 or RF transmitter 16c in his hand. The remote control device 24 could incorporate a microphone 30 adapted to pick up ambient noise and the system can be programmed using the processor 18 to cancel the ambient noise to provide a better quality sound at an individual's location. Directional speakers can be used so the rest of the room hears little noise. Another embodiment is where the system keeps a person's personal space quiet using noise cancellation speaker technology. The user would have a microphone 30 on him and the speakers would produce sound to counteract the noise waves in the environment.

The remote control device 24 could include a touch screen 32 representative of the room 20 and/or four buttons 34 to manually adjust the speakers to direct sound toward a sound sweetspot location 36 within a room 20 or the person(s) 14a,14b in the room. The touch screen 32 can show multiple people and multiple speakers as well as what locations and directions the speakers are in. With the remote, the sweetspot 36 can moved around the room.

The system can be programmed to effectively be a location aware acoustic feedback system. In such an embodiment, there are two modes of operation when two or more people are in a room. Each individual speaker 12 moves or directionally aligns itself with the location of a designated individual in the room 20 or the system can be programmed to calculate an optimal midpoint location 38 and to direct all individual speakers 12 toward that optimal midpoint location 38.

The location aware system uses for highly directional speakers 12 that allow for the rest of the room area to be not as loud for others that do not wish to listen, thereby also allowing for a richer sound. These highly directional speakers 12 can be adapted to include a parabolic dish 40 that can be attached to and behind the speaker 12 or not attached to the speaker 12 but located behind the speaker 12. The speaker assembly can be enclosed in a speaker box housing or other type of design. The speaker within the dish 40 can move which moves the sweetspot location 36 (or person 14a, group of persons 14b) of the directional sound or the whole dish 40 in unison with the speaker 12 can move.

It should be understood that the preceding is merely a detailed description of one or more embodiments of this invention and that numerous changes to the disclosed embodiments can be made in accordance with the disclosure herein without departing from the spirit and scope of the invention. The preceding description, therefore, is not meant to limit the scope of the invention. Rather, the scope of the invention is to be determined only by the appended claims and their equivalents.

What is claimed is:

1. A system for providing focused directional sound in an audio system comprising an audio speaker system having a speaker comprising at least one tweeter speaker or a general full range speaker, the system further comprising:
means for sensing real-time movements of a person or a group of persons in a room and adjusting a speaker movement without manually physically rotating said speaker;
a servo device associated with said speaker, said servo device being configured so as to rotate said speaker to direct an audio sound from said speaker toward said person or said group of persons as said person moves or said group of persons move in said room; and
processing means for analyzing a change of position data related to said movements and for electrically activating said servo device.

2. The system according to claim 1, wherein said means for sensing real-time movements of said person or a group of persons comprises:
an infrared sensor located at said speaker, said infrared sensor having electronic circuitry for monitoring said movements within a room of said person or group of persons using thermal sensing technology.

3. The system according to claim 1, wherein said means for sensing real-time movements of said person or a group of persons comprises:
a radio frequency system comprising a radio frequency first component located at said speaker and a corresponding radio frequency second component to be carried by said person or one of said group of persons.

4. The system according to claim 1, wherein said means for sensing real-time movements of said person or a group of persons comprises:
a camera located at said speaker, said camera being in electronic communication with a facial recognition software wherein said software is programmed to recognize said person or said one of said group of persons and to track said movements of said person or said one of said group of persons.

5. The system according to claim 1, wherein said speaker is a satellite speaker.

6. The system according to claim 1, wherein said speaker comprises two or more satellite speakers.

7. The system according to claim 6, further comprising volume reduction or attenuation and delay processing means for adjusting a volume of one of said satellite speakers as said person or group of persons move closer to said one of said satellite speakers.

8. The system according to claim 3, further comprising a remote control device incorporating said radio frequency first component or second component.

9. The system according to claim 8, wherein said remote control device has programmed means for manually pre-setting a speaker direction toward a desired pre-set location.

10. The system according to claim 8, wherein said remote control device has programmed means for compensating between a physical location of said remote control device and a person's ears.

11. The system according to claim 9, wherein said remote control device further comprises a microphone pick-up component configured to pick-up ambient noise, said system being programmed to cancel out said ambient noise.

12. The system according to claim 9, wherein said remote control device further comprises a touch screen representative of said room and indicating speaker locations and people or sweetspot locations within the room.

13. The system according to claim 9, wherein said remote control device further comprises means for manually adjusting a directional sound of individual speakers within said MOM.

14. The system according to claim 1, wherein said system has means for directionally aligning said at least one speaker to direct sound toward a desired sound sweetspot location within said room or toward said person or said group of persons within said room, or toward a calculated optimal midpoint location within said room.

15. The system according to claim 1, wherein said speaker further comprises a parabolic dish, wherein said speaker is rotatable within the said parabolic dish or said parabolic dish is in mechanical communication with said speaker such that said parabolic dish and said speaker rotates in unison or said speaker moves on two axes inside said parabolic dish.

16. A method for providing focused directional sound in an audio system comprising an audio speaker system having a speaker comprising at least one tweeter speaker or a general full range speaker, the method comprising:
providing means for sensing real-time movements of a person or a group of persons in a room and adjusting a speaker movement without manually physically rotating said speaker;
providing a servo device associated with said speaker, said servo device being configured so as to rotate said tweeter to direct an audio sound from said speaker toward said person or said group of persons as said person moves or said group of persons move in said room; and
providing processing means for analyzing a change of position data related to said movements and for electrically activating said servo device.

17. The method according to claim 16, wherein said means for sensing real-time movements of said person or a group of persons comprises:
an infrared sensor located at said speaker, said infrared sensor having electronic circuitry for monitoring said movements within a room of said person or group of persons using thermal sensing technology.

18. The method according to claim 16, wherein said means for sensing real-time movements of said person or a group of persons comprises:
a radio frequency system comprising a radio frequency first component located at said speaker and a corresponding radio frequency second component to be carried by said person or one of said group of persons.

19. The method according to claim 16, wherein said means for sensing real-time movements of said person or a group of persons comprises:
a camera located at said speaker, said camera being in electronic communication with a facial recognition software wherein said software is programmed to recognize said person or said one of said group of persons and to track said movements of said person or said one of said group of persons.

20. The method according to claim 16, wherein said speaker is a satellite speaker.

21. The method according to claim 16, wherein said speaker comprises two or more satellite speakers.

22. The method according to claim 21, further comprising providing volume reduction or attenuation and delay processing means for adjusting a volume of one of said satellite speakers as said person or group of persons move closer to said one of said satellite speakers.

23. The method according to claim 18, further comprising a remote control device incorporating said radio frequency first component or second component.

24. The method according to claim 16, wherein said remote control device has programmed means for manually pre-setting a speaker direction toward a desired pre-set location.

25. The method according to claim 16, wherein said remote control device has programmed means for compensating between a physical location of said remote control device and a person's ears.

26. The method according to claim 24, wherein said remote control device further comprises a microphone pick-up component configured to pick-up ambient noise, said programmed means being programmed to cancel out said ambient noise.

27. The method according to claim 24, wherein said remote control device further comprises a touch screen representative of said room and indicating speaker locations and people or sweetspot locations within the room.

28. The method according to claim 24, wherein said remote control device further comprises means for manually adjusting a directional sound of individual speakers within said MOM.

29. The method according to claim 16, further comprising providing means for directionally aligning said speaker to direct sound toward a desired sound sweetspot location within said room or toward said person or said group of persons within said room, or toward a calculated optimal midpoint location within said room.

30. The method according to claim 16, wherein said speaker further comprises a parabolic dish, wherein said at least one speaker is rotatable within the said parabolic dish or said parabolic dish is in mechanical communication with said speaker such that said parabolic dish and said speaker rotates in unison or said speaker moves on two axes inside said parabolic dish.

31. A method for providing focused directional sound in an audio system comprising an audio speaker system having a speaker comprising at least one tweeter speaker or a general full range speaker, the method comprising:
tracking a movement of a person or a group of persons in a room using means for sensing real-time movements of said person or said group of persons in a room;
activating a servo device associated with said speaker, said servo device being configured so as to rotate said speaker to direct an audio sound from said speaker toward said person or said group of persons as said person moves or said group of persons move in said room; and
using processing means for analyzing a change of position data related to said movements and for electrically activating said servo device, automatically rotating said servo device so as to rotate said speaker to direct said audio sound toward said person or said group of persons as said person moves or said group of persons move in said room.

32. The method according to claim 31, wherein said means for sensing real-time movements of said person or a group of persons comprises:
an infrared sensor located at said speaker, said infrared sensor having electronic circuitry for monitoring said movements within a room of said person or group of persons using thermal sensing technology.

33. The method according to claim 31, wherein said means for sensing real-time movements of said person or a group of persons comprises:
a radio frequency system comprising a radio frequency first component located at said speaker and a corresponding radio frequency second component to be carried by said person or one of said group of persons.

34. The method according to claim 31, wherein said means for sensing real-time movements of said person or a group of persons comprises:
a camera located at said speaker, said camera being in electronic communication with a facial recognition software wherein said software is programmed to recognize said person or said one of said group of persons and to track said movements of said person or said one of said group of persons.

35. The method according to claim 31, wherein said speaker is a satellite speaker.

36. The method according to claim 31, wherein said speaker comprises two or more satellite speakers.

37. The method according to claim 36, further comprising adjusting a volume of one of said satellite speakers as said person or group of persons move closer to said one of said satellite speakers using volume reduction or attenuation and delay processing means for making such adjustments, wherein when said speaker is close to a listener, a sound is decreased or delayed to have sound waves hit the listener in sync as if said listener is optimally between two speakers.

38. The method according to claim 33, further comprising a remote control device incorporating said radio frequency first component or second component.

39. The method according to claim 38, wherein said remote control device has programmed means for manually pre-setting a speaker direction toward a desired pre-set location.

40. The method according to claim 38, wherein said remote control device has programmed means for compensating between a physical location of said remote control device and a person's ears.

41. The method according to claim 39, wherein said remote control device further comprises a microphone pick-up component configured to pick-up ambient noise, said programmed means being programmed to cancel out said ambient noise.

42. The method according to claim 39, wherein said remote control device further comprises a touch screen representative of said room and indicating speaker locations and people or sweetspot locations within the room.

43. The method according to claim 39, wherein said remote control device further comprises means for manually adjusting a directional sound of individual speakers within said MOM.

44. The method according to claim 31, further comprising directionally aligning said speaker to direct sound toward a desired sound sweetspot location within said room or toward said person or said group of persons within said room, or toward a calculated optimal midpoint location within said room.

45. The method according to claim 31, wherein said speaker further comprises a parabolic dish, wherein said speaker is rotatable within the said parabolic dish or said parabolic dish is in mechanical communication with said speaker such that said parabolic dish and said speaker rotates in unison or said speaker moves on two axes inside said parabolic dish.
